(19) United States
(12) Patent Application Publication
(10) Pub. No.: US 2026/0317900 A1
(43) Pub. Date: Oct. 15, 2026

(54) SUBSTRATE PROCESSING METHOD, METHOD OF MANUFACTURING SEMICONDUCTOR DEVICE, RECORDING MEDIUM AND SUBSTRATE PROCESSING APPARATUS

(71) Applicant: KOKUSAI ELECTRIC CORPORATION, Tokyo (JP)

(72) Inventors: Shogo HAYASAKA, Toyama-shi (JP); Arito OGAWA, Toyama-shi (JP)

(73) Assignee: KOKUSAI ELECTRIC CORPORATION, Tokyo (JP)

(21) Appl. No.: 19/629,471

(22) Filed: Mar. 26, 2026

Related U.S. Application Data
(63) Continuation of application No. PCT/JP2023/036231, filed on Oct. 4, 2023.

(51) Int. Cl. C23C 16/455; C23C 16/06; H10P 14/43

(52) U.S. Cl. CPC C23C 16/45523; C23C 16/06; C23C 16/45519; C23C 16/45557; H10P 14/43

(57) ABSTRACT

Provided is a technique capable of forming a low-resistance film that includes: (a) supplying a first element-containing gas to a substrate; (b) supplying a first reducing gas to the substrate; (c) supplying a second reducing gas to the substrate; (d) supplying an inert gas to the substrate; (e) performing (a) and (b) at least partially in parallel while performing (d), and increasing a supply flow rate of the inert gas when performing (b); and (f) performing (e) and (c) a predetermined number of times to form a film containing the first element on the substrate.

### CROSS-REFERENCE TO RELATED APPLICATIONS

This application is a Bypass Continuation Application of PCT International Application No. PCT/JP2023/036231, filed on Apr. 10, 2023, in the WIPO, the entire contents of which are hereby incorporated by reference.

### BACKGROUND

### Field

The present disclosure relates to a method of processing a substrate, a method of manufacturing a semiconductor device, a recording medium, and a substrate processing apparatus.

### Description of the Related Art

For example, a low-resistance metal film is used as a word line of a 3D NAND flash memory or a DRAM having a three-dimensional structure. In addition, a barrier film may be formed between the metal film and an insulating film.

### SUMMARY

The present disclosure provides a technique capable of forming a low-resistance film.

According to one aspect of the present disclosure, there is provided a technique that includes: (a) supplying a first element-containing gas to a substrate; (b) supplying a first reducing gas to the substrate; (c) supplying a second reducing gas to the substrate; (d) supplying an inert gas to the substrate; (e) performing (a) and (b) at least partially in parallel while performing (d), and increasing a supply flow rate of the inert gas when performing (b); and (f) performing (e) and (c) a predetermined number of times to form a film containing the first element on the substrate.

### BRIEF DESCRIPTION OF THE DRAWINGS

FIG. 1 is a longitudinal cross-sectional view illustrating an outline of a substrate processing apparatus.

FIG. 2 is a schematic transverse cross-sectional view taken along line A-A in FIG. 1.

FIG. 3 is a schematic configuration diagram of a controller of the substrate processing apparatus and is a diagram illustrating a control system of the controller with a block diagram.

FIG. 4 is a diagram illustrating a substrate processing flow.

FIG. 5 is a diagram illustrating a substrate processing sequence.

FIG. 6 is a diagram illustrating a substrate processing sequence.

### DETAILED DESCRIPTION

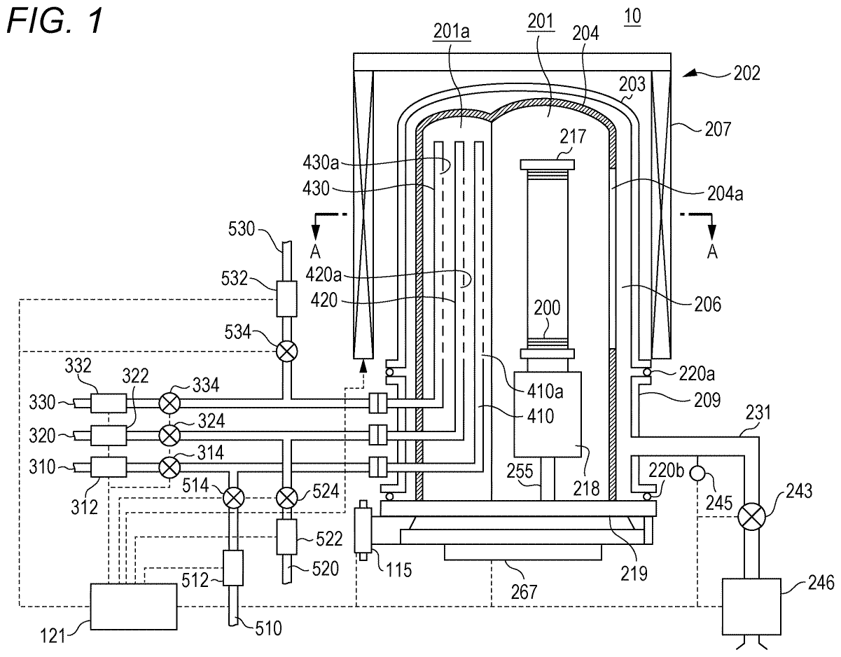

One aspect of the present disclosure will be described below mainly with reference to FIGS. 1 to 6. Note that the drawings used in the following description are all schematic, and a dimensional relationship between elements, a ratio between elements, and the like illustrated in the drawings do not necessarily coincide with actual ones. Between a plurality of drawings, the dimensional relationships between the elements, the ratios between the elements, and the like do not necessarily coincide with each other.

### (1) Configuration of Substrate Processing Apparatus

A substrate processing apparatus 10 includes a process furnace 202 including a heater 207 serving as a heating means (heating mechanism or heating system). The heater 207 has a cylindrical shape and is vertically installed by being supported by a heater base (not illustrated) serving as a holding plate.

Inside the heater 207, an outer tube 203 constituting a reaction container (process container) (hereinafter, referred to as an outer tube 203) is disposed concentrically with the heater 207. The outer tube 203 is made of a heat-resistant material such as quartz (SiO₂) or silicon carbide (SiC). The outer tube 203 is formed in a cylindrical shape with an upper end closed and a lower end opened. A manifold 209 (hereinafter, referred to as an MF 209) is disposed below the outer tube 203 concentrically with the outer tube 203. The MF 209 is made of a metal material such as stainless steel (SUS). The MF 209 is formed in a cylindrical shape with an upper end and a lower end opened. An O-ring 220a serving as a seal member is disposed between an upper end portion of the MF 209 and the outer tube 203. The MF 209 is supported by the heater base, and thus, the outer tube 203 is vertically installed.

Inside the outer tube 203, an inner tube 204 constituting the reaction container (hereinafter, referred to as an inner tube 204) is disposed. The inner tube 204 is made of the above-described heat-resistant material. The inner tube 204 is formed in a cylindrical shape with an upper end closed and a lower end opened. The outer tube 203, the inner tube 204, and the MF 209 mainly constitute the process container (reaction container). In a cylindrical hollow portion of the process container (inside the inner tube 204), a process chamber 201 is formed. The process chamber 201 is also referred to as a space containing wafers 200.

The process chamber 201 is configured to be able to house the wafers 200 serving as substrates in a state where the wafers 200 are arranged in multiple stages in the vertical direction in a horizontal posture by a boat 217 described later.

In the process chamber 201, nozzles 410, 420, and 430 are disposed so as to penetrate a side wall of the MF 209 and the inner tube 204. The nozzles 410, 420, and 430 are connected to gas supply pipes 310, 320, and 330, respectively. Note that the process furnace 202 of the present disclosure is not limited to the above-described form.

Mass flow controllers (MFCs) 312, 322, and 332 which are flow rate controllers are disposed in the gas supply pipes 310, 320, and 330, respectively. In addition, valves 314, 324, and 334 which are on-off valves are disposed in the gas supply pipes 310, 320, and 330, respectively. To downstream sides of the valves 314, 324, and 334 of the gas supply pipes 310, 320, and 330, gas supply pipes 510, 520, and 530 that supply an inert gas are connected, respectively. MFCs 512, 522, and 532 which are flow rate controllers, and valves 514, 524, and 534 which are on-off valves, are disposed in the gas supply pipes 510, 520, and 530 in this order from an upstream side, respectively.

The nozzles 410, 420, and 430 are connected to distal end portions of the gas supply pipes 310, 320, and 330, respectively. The nozzles 410, 420, and 430 are formed as L-shaped nozzles, and horizontal portions thereof are disposed so as to penetrate the side wall of the MF 209 and the inner tube 204. Vertical portions of the nozzles 410, 420, and 430 are disposed inside a channel-shaped (groove-shaped) preliminary chamber 201a which is formed so as to project outwardly in a radial direction of the inner tube 204 and to extend in the vertical direction, and are disposed in the preliminary chamber 201a so as to extend to an upper side (an upper side in the arrangement direction of the wafers 200) along an inner wall of the inner tube 204.

The nozzles 410, 420, and 430 are disposed so as to extend from a lower area of the process chamber 201 to an upper area of the process chamber 201, and have a plurality of gas supply holes 410a, a plurality of gas supply holes 420a, and a plurality of gas supply holes 430a at positions facing the wafers 200, respectively. As a result, a process gas is supplied from each of the gas supply holes 410a, 420a, and 430a of the nozzles 410, 420, and 430 to the wafers 200. The plurality of gas supply holes 410a, the plurality of gas supply holes 420a, and the plurality of gas supply holes 430a are formed from a lower portion to an upper portion of the inner tube 204, have the same opening area, and are formed at the same opening pitch. Note that the gas supply holes 410a, 420a, and 430a are not limited to the above-described form. For example, the opening area may be gradually increased from a lower portion to an upper portion of the inner tube 204. As a result, flow rates of gases supplied from the gas supply holes 410a, 420a, and 430a can be made more uniform.

The plurality of gas supply holes 410a, the plurality of gas supply holes 420a, and the plurality of gas supply holes 430a of the nozzles 410, 420, and 430 are formed at height positions from a lower portion to an upper portion of the boat 217 described later. Therefore, a process gas supplied from the gas supply holes 410a, 420a, and 430a of the nozzles 410, 420, and 430 into the process chamber 201 is supplied to the entire region of the wafers 200 housed from the lower portion to the upper portion of the boat 217. The nozzles 410, 420, and 430 only need to be disposed so as to extend from a lower area to an upper area of the process chamber 201, but are preferably disposed so as to extend to the vicinity of a ceiling of the boat 217.

From the gas supply pipe 310, a first element-containing gas containing a first element is supplied as a process gas into the process chamber 201 via the MFC 312, the valve 314, and the nozzle 410.

From the gas supply pipe 320, a first reducing gas is supplied as a process gas into the process chamber 201 via the MFC 322, the valve 324, and the nozzle 420.

From the gas supply pipe 330, a second reducing gas is supplied as a process gas into the process chamber 201 via the MFC 332, the valve 334, and the nozzle 430.

From the gas supply pipes 510, 520, and 530, an inert gas is supplied into the process chamber 201 via the MFCs 512, 522, and 532, the valves 514, 524, and 534, and the nozzles 410, 420, and 430, respectively.

The gas supply pipes 310, 320, and 330, the MFCs 312, 322, and 332, the valves 314, 324, and 334, and the nozzles 410, 420, and 430 mainly constitute a process gas supplier, but only the nozzles 410, 420, and 430 may be considered as the process gas supplier. The process gas supplier may be simply referred to as a gas supplier. When the first element-containing gas is caused to flow from the gas supply pipe 310, the gas supply pipe 310, the MFC 312, and the valve 314 mainly constitute a first gas supplier, but the nozzle 410 may be included in the first gas supplier. When the first reducing gas is caused to flow from the gas supply pipe 320, the gas supply pipe 320, the MFC 322, and the valve 324 mainly constitute a second gas supplier, but the nozzle 420 may be included in the second gas supplier. When the second reducing gas is caused to flow from the gas supply pipe 330, the gas supply pipe 330, the MFC 332, and the valve 334 mainly constitute a third gas supplier, but the nozzle 430 may be included in the third gas supplier. The gas supply pipes 510, 520, and 530, the MFCs 512, 522, and 532, and the valves 514, 524, and 534 mainly constitute a fourth gas supplier.

In a gas supply method in the present embodiment, a gas is transferred through the nozzles 410, 420, and 430 disposed in the preliminary chamber 201a inside an annular and vertically long space constituted by an inner wall of the inner tube 204 and end portions of a plurality of wafers 200.

Then, the gas is ejected into the inner tube 204 from the plurality of gas supply holes 410a, 420a, and 430a of the nozzles 410, 420, and 430, the gas supply holes being formed at positions facing the wafers. More specifically, the gas is ejected in a direction parallel to surfaces of the wafers 200 through the gas supply holes 410a of the nozzle 410, the gas supply holes 420a of the nozzle 420, and the gas supply holes 430a of the nozzle 430.

An exhaust hole (exhaust port) 204a is a through-hole formed in a side wall of the inner tube 204 at a position facing the nozzles 410, 420, and 430 and is, for example, a slit-shaped through-hole opened so as to be elongated in the vertical direction. The gas which has been supplied into the process chamber 201 from the gas supply holes 410a, 420a, and 430a of the nozzles 410, 420, and 430 and has flowed on the surfaces of the wafers 200 flows into an exhaust path 206 which is a gap formed between the inner tube 204 and the outer tube 203 via the exhaust hole 204a. Then, the gas that has flowed into the exhaust path 206 flows into an exhaust pipe 231 and is discharged to the outside of the process furnace 202.

The exhaust hole 204a is formed at a position facing side surfaces of the plurality of wafers 200, and the gas supplied from the gas supply holes 410a, 420a, and 430a to the vicinity of the wafers 200 in the process chamber 201 flows in the horizontal direction and then flows into the exhaust path 206 via the exhaust hole 204a. The exhaust hole 204a is not limited to being formed as a slit-shaped through-hole and may be formed by a plurality of holes.

In the MF 209, the exhaust pipe 231 that discharges an atmosphere in the process chamber 201 is disposed. To the exhaust pipe 231, a pressure sensor 245 serving as a pressure detector that detects a pressure in the process chamber 201, an auto pressure controller (APC) 243 serving as an exhaust valve, and a pump 246 serving as a vacuum exhaust device are connected in this order from an upstream side. The APC 243 can perform vacuum exhaust and vacuum exhaust stop in the process chamber 201 by opening and closing the valve in a state where the pump 246 is operated, and furthermore, can adjust a pressure in the process chamber 201 by adjusting an exhaust conductance by adjusting a degree of valve opening in a state where the pump 246 is operated. The exhaust hole 204a, the exhaust path 206, the exhaust pipe 231, the APC 243, and the pressure sensor 245 mainly constitute an exhauster. At least the exhaust port 204a may be considered as an exhauster. The pump 246 may be included in the exhauster.

Below the MF 209, a seal cap 219 (hereinafter, referred to as a cap 219) serving as a furnace opening lid capable of airtightly closing a lower end opening of the MF 209 is disposed. The cap 219 is configured to be brought into contact with a lower end of the MF 209 from a lower side in the vertical direction. The cap 219 is made of a metal material such as SUS. The cap 219 is formed in a disk shape. On an upper surface of the cap 219, an O-ring 220b serving as a seal member in contact with the lower end of the MF 209 is disposed. On a side of the cap 219 opposite to the process chamber 201, a rotation mechanism 267 that rotates the boat 217 that houses the wafers 200 is installed. A rotating shaft 255 of the rotation mechanism 267 penetrates the cap 219 and is connected to the boat 217. The rotation mechanism 267 is configured to rotate the boat 217, thereby rotating the wafers 200. The cap 219 is configured to be raised and lowered in the vertical direction by a boat elevator 115 (hereinafter, referred to as an elevator 115) serving as a raising/lowering mechanism vertically installed outside the outer tube 203. The elevator 115 is configured to be able to load the boat 217 into the process chamber 201 and unload the boat 217 out of the process chamber 201 by raising and lowering the cap 219. The elevator 115 is configured as a transfer device (transfer mechanism) that transfers the boat 217 and the wafers 200 housed in the boat 217 to the inside and the outside of the process chamber 201.

The boat 217 serving as a substrate support is configured such that a plurality of, for example, 1 to 200 wafers 200 can be arranged at intervals in the vertical direction in a horizontal posture and in a state where centers thereof are aligned with each other. The boat 217 is made of a heat-resistant material such as quartz or SiC. In a lower portion of the boat 217, a heat insulating plate 218 made of a heat-resistant material such as quartz or SiC is supported in a horizontal posture in multiple stages (not illustrated). With this configuration, heat from the heater 207 is less likely to be transferred to the cap 219 side. Note that the present embodiment is not limited to the above-described form. For example, a heat insulating tube configured as a cylindrical member made of a heat resistant material such as quartz or SiC may be disposed without disposing the heat insulating plate 218 at the lower portion of the boat 217.

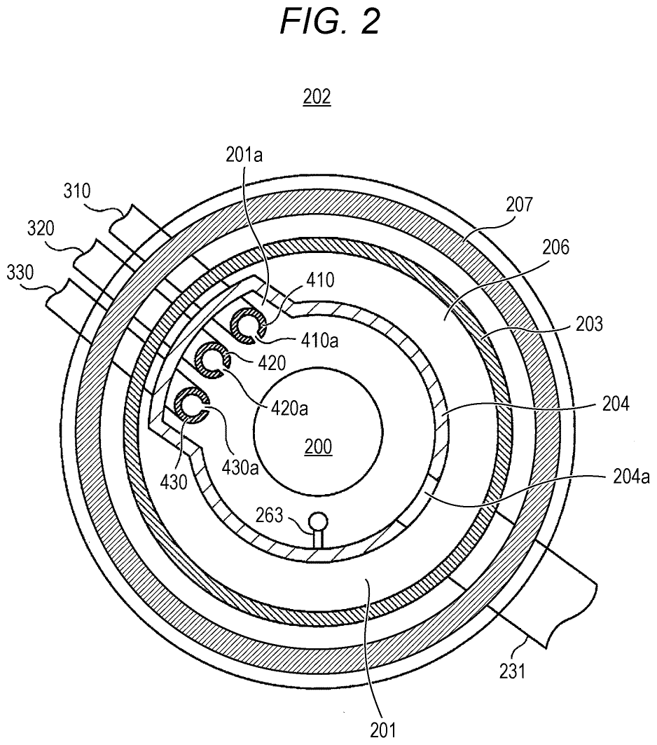

As illustrated in FIG. 2, a temperature sensor 263 serving as a temperature detector is installed in the inner tube 204 and is configured such that a temperature in the process chamber 201 has a desired temperature distribution by adjusting an energization amount to the heater 207 on the basis of temperature information detected by the temperature sensor 263. The temperature sensor 263 is configured in an L shape similarly to the nozzles 410, 420, and 430 and is disposed along an inner wall of the inner tube 204.

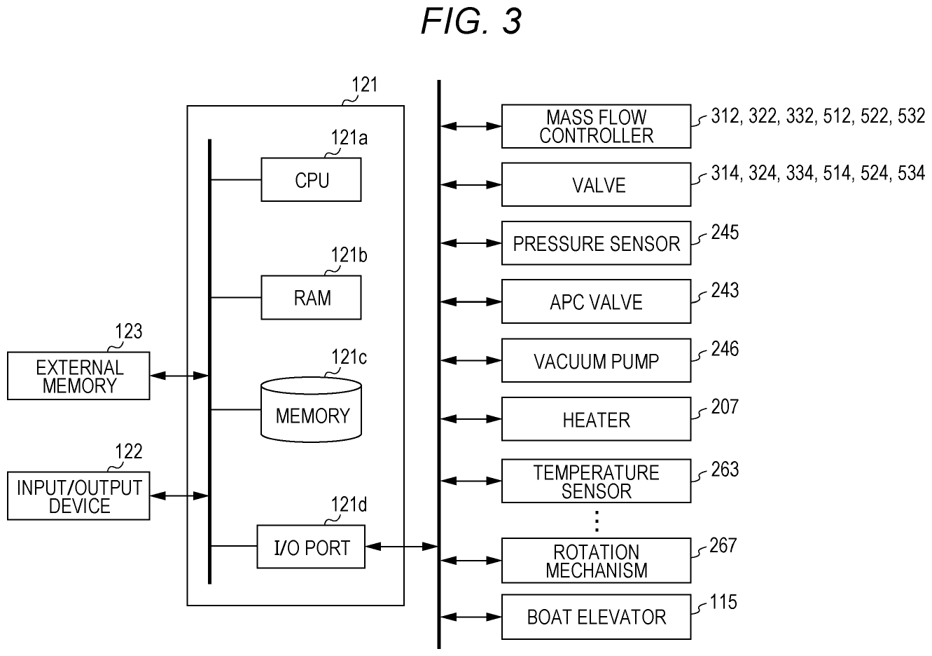

As illustrated in FIG. 3, a controller 121 as a controller (controlling means) is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus. An input/output device 122 configured as, for example, a touch panel is connected to the controller 121. Note that the substrate processing apparatus may be configured to include one controller or may be configured to include a plurality of controllers. That is, control for performing a processing sequence described later may be performed using one controller or a plurality of controllers. In addition, the plurality of controllers may be configured as a control system in which the controllers are mutually connected by a wired or wireless communication network, and control for performing a processing sequence described later may be performed by the entire control system. In the present specification, the term “controller” may include one controller, a plurality of controllers, or a control system including a plurality of controllers.

The memory 121c is constituted by, for example, a flash memory or a hard disk drive (HDD). The memory 121c readably stores a control program that controls an operation of the substrate processing apparatus, a process recipe (hereinafter, referred to as a recipe) in which a procedure, a condition, and the like of a method of manufacturing a semiconductor device described later are described, and the like. The recipe is a combination formed so as to cause the controller 121 to execute steps in a method of manufacturing a semiconductor device described later to obtain a predetermined result, and functions as a program. Hereinafter, the recipe, the control program, and the like, are also collectively and simply referred to as a program. In the present disclosure, the term “program” may include only the recipe alone, only the control program alone, or a combination of the recipe and the control program. The RAM 121b is configured as a memory area in which a program, data, and the like read by the CPU 121a are temporarily stored.

The I/O port 121d is connected to the MFCs 312, 322, 332, 512, 522, and 532, the valves 314, 324, 334, 514, 524, and 534, the pressure sensor 245, the APC 243, the pump 246, the heater 207, the temperature sensor 263, the rotation mechanism 267, the elevator 115, and the like, described above in a controllable manner. Here, the connection includes being directly electrically connected, being indirectly connected, and being configured to be able to directly or indirectly transmit and receive an electric signal.

The CPU 121a is configured to read a control program from the memory 121c to execute the control program and to read a recipe and the like from the memory 121c in response to an input of an operation command from the input/output device 122 or the like. The CPU 121a is configured to control various gases flow rate adjustment operations by the MFCs 312, 322, 332, 512, 522, and 532, opening/closing operations of the valves 314, 324, 334, 514, 524, and 534, an opening/closing operation of the APC 243, a pressure adjustment operation by the APC 243 based on the pressure sensor 245, a temperature adjustment operation of the heater 207 based on the temperature sensor 263, start and stop of the pump 246, a rotation and rotation speed adjustment operation of the boat 217 by the rotation mechanism 267, a raising/lowering operation of the boat 217 by the elevator 115, an operation of housing the wafers 200 into the boat 217, and the like according to the contents of the read recipe.

The controller 121 can install, in a computer, the above-described program stored in an external memory (for example, a magnetic disk such as a hard disk, an optical disk such as a CD or a DVD, or a semiconductor memory such as a USB memory or a memory card) 123. The memory 121c and the external memory 123 are configured as computer-readable recording media. Hereinafter, these are also collectively and simply referred to as a recording medium. In the present disclosure, the term “recording medium” may include only the memory 121c alone, only the external memory 123 alone, or both of them. A program may be provided to a computer using a communication means such as the Internet or a dedicated line without use of the external memory 123.

### (2) Substrate Processing Step

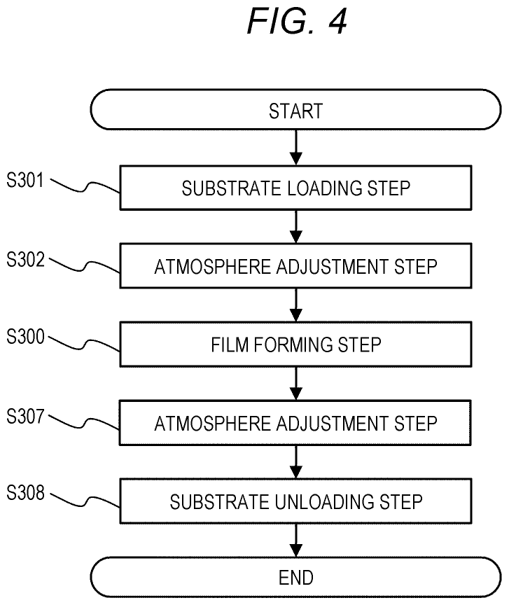

As a step of a semiconductor device (device) manufacturing process, an example of a step of forming a thin film on the wafer 200 will be described with reference to FIGS. 4 to 6. In the following description, operations of portions constituting the substrate processing apparatus 10 are controlled by the controller 121.

A substrate processing step (semiconductor device manufacturing process) according to the present embodiment includes:
(a) supplying a first element-containing gas to a wafer 200;
(b) supplying a first reducing gas to the wafer 200;
(c) supplying a second reducing gas to the wafer 200;
(d) supplying an inert gas to the wafer 200;
(e) performing (a) and (b) at least partially in parallel while performing (d), and increasing a supply flow rate of the inert gas when performing (b); and
(f) performing (e) and (c) a predetermined number of times to form a film containing the first element on the wafer 200.

In the present specification, the term “wafer” may mean a “wafer itself” or a “laminate of a wafer and a predetermined layer, film, or the like formed on a surface of the wafer”. In the present specification, the term “surface of a wafer” may mean a “surface of a wafer itself” or a “surface of a predetermined layer, film, or the like formed on the wafer”. The term “substrate” in the present specification is synonymous with the term “wafer”.

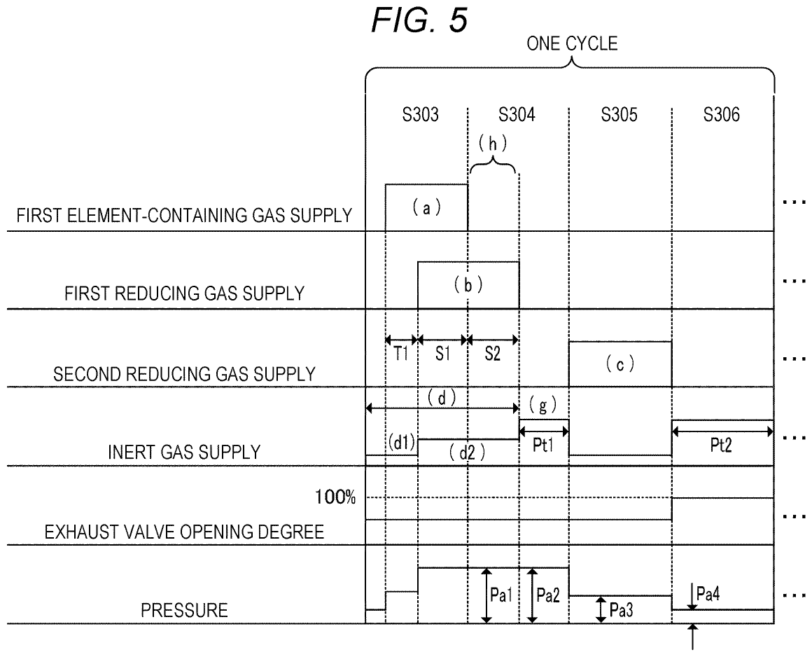

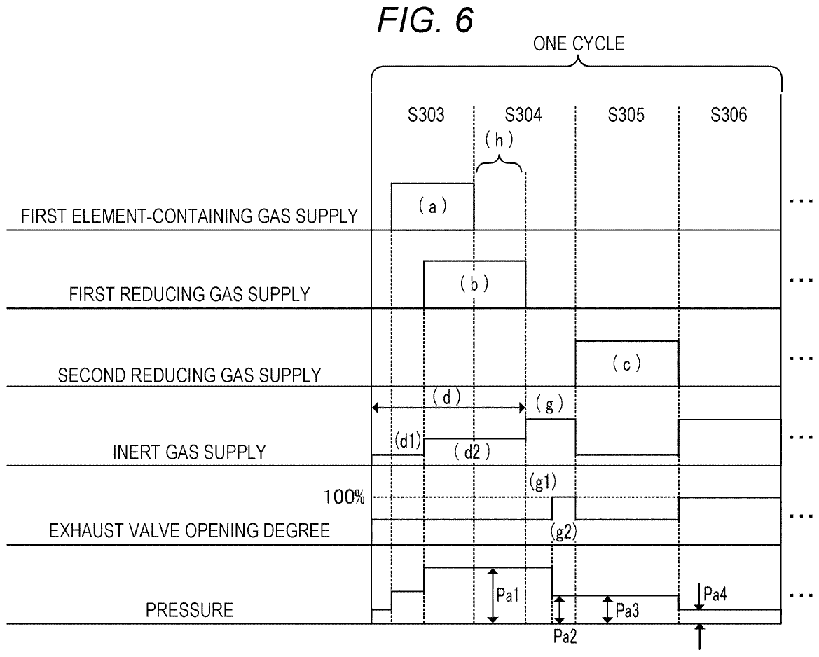

Hereinafter, a flow and a gas supply sequence of a device manufacturing method of the present disclosure will be described with reference to FIGS. 4 to 6. Note that, in FIGS. 5 and 6, the horizontal axis represents time, and the vertical axis represents a gas supply amount, a valve opening degree, and a pressure. The supply amount, the valve opening degree, and the pressure are in arbitrary units.

### Substrate Loading Step S301

When the plurality of wafers 200 are loaded into the boat 217, as illustrated in FIG. 1, the boat 217 supporting the plurality of wafers 200 is lifted by the elevator 115 and is loaded into the process chamber 201. In this state, the cap 219 closes a lower end opening of the reaction tube 203 via the O-ring 220b.

### Atmosphere Adjustment Step S302

The inside of the process chamber 201 is exhausted by the pump 246 so as to have a desired pressure (degree of vacuum). At this time, the pressure in the process chamber 201 is measured by the pressure sensor 245, and the APC 243 is feedback-controlled on the basis of the measured pressure information (pressure adjustment). The pump 246 maintains a state of being constantly operated at least until the processing on the wafers 200 is completed. The inside of the process chamber 201 is heated by the heater 207 so as to have a desired temperature. At this time, the energization amount to the heater 207 is feedback-controlled on the basis of the temperature information detected by the temperature sensor 263 such that the inside of the process chamber 201 has a desired temperature distribution (temperature adjustment). The inside of the process chamber 201 is continuously heated by the heater 207 at least until the processing on the wafers 200 is completed. Here, the temperature of the heater 207 is set to a temperature at which the temperature of the wafers 200 is within a range of, for example, 300 to 700 °C.

### Film Forming Step S300

Next, as illustrated in FIGS. 5 and 6, a film forming step in which a film forming step S300 is performed includes a first step S303, a second step S304, a third step S305, and a fourth step S306.

### [First Step S303] (First Element-Containing Gas Supply)

The valve 314 is opened to cause a first element-containing gas which is a source gas to flow into the gas supply pipe 310. A flow rate of the first element-containing gas is adjusted by the MFC 312, and the first element-containing gas is supplied from the gas supply holes 410a of the nozzle 410 into the process chamber 201, and discharged from the exhaust pipe 231. At this time, the first element-containing gas is supplied to the wafers 200. In parallel with this, the valve 514 is opened to cause an inert gas to flow into the gas supply pipe 510. A flow rate of the inert gas which has flowed through the gas supply pipe 510 is adjusted by the MFC 512, and the inert gas is supplied into the process chamber 201 together with the first element-containing gas and discharged from the exhaust pipe 231. At this time, the valves 524 and 534 are opened to cause the inert gas to flow into the gas supply pipes 520 and 530 in order to prevent entry of the first element-containing gas into the nozzles 420 and 430. The inert gas is supplied into the process chamber 201 via the gas supply pipes 320 and 330 and the nozzles 420 and 430 and discharged from the exhaust pipe 231.

Here, examples of the first element include metal elements of Groups 3 to 13 of the periodic table and elements of Group 14 of the periodic table. Examples of this element include the following elements. Group 3 elements such as yttrium (Y) and lanthanum (La), Group 4 elements such as cerium (Ce), titanium (Ti), zirconium (Zr), and hafnium (Hf), Group 5 elements such as vanadium (V), niobium (Nb), and tantalum (Ta), Group 6 elements such as chromium (Cr), molybdenum (Mo), and tungsten (W), a Group 8 element such as ruthenium (Ru), a Group 10 element such as nickel (Ni), a Group 12 element such as zinc (Zn), Group 13 elements such as aluminum (Al), gallium (Ga), and indium (In), and Group 14 elements such as silicon (Si) and germanium (Ge).

The first element-containing gas is a gas containing the first element and a halogen element. Therefore, the first element-containing gas is preferably a gas containing the above-described element and a halogen element. Examples of such a gas include the following gases. Examples of the gas include a titanium chloride (TiCl₄) gas, a hafnium chloride (HfCl₄) gas, a zirconium chloride (ZrCl₄) gas, a tungsten hexafluoride (WF₆) gas, a tungsten hexachloride (WCl₆) gas, a tungsten pentachloride (WCl₅) gas, a molybdenum pentachloride (MoCl₅) gas, a molybdenum dichloride dioxide (MoO₂Cl₂) gas, a molybdenum tetrachloride oxide (MoOCl₄) gas, a molybdenum hexafluoride (MoF₆) gas, a molybdenum difluoride dioxide (MoO₂F₂) gas, a molybdenum tetrafluoride oxide (MoOF₄) gas, an aluminum chloride (AlCl₃) gas, a silicon tetrachloride (SiCl₄) gas, a dichlorosilane (SiH₂Cl₂) gas, a hexachlorodisilane (Si₂Cl₆) gas, and a trichlorosilane (SiHCl₃) gas. A gas that reacts with a part of a first reducing gas and a second reducing gas described later to generate a hydrogen halide is preferably used.

As the inert gas, for example, a rare gas such as an argon (Ar) gas, a helium (He) gas, a neon (Ne) gas, or a xenon (Xe) gas can be used in addition to a nitrogen (N₂) gas. One or more of these can be used as the inert gas.

At this time, the APC 243 is adjusted to set a pressure in the process chamber 201 to a pressure within a range of, for example, 1 to 3990 Pa. A supply flow rate of the first element-containing gas controlled by the MFC 312 is a flow rate within a range of, for example, 0.1 to 2.0 slm. Each of the supply flow rates of the inert gas controlled by the MFCs 512, 522, and 532 is a flow rate within a range of, for example, 0.1 to 20 slm.

At this time, the gases flowing into the process chamber 201 are the first element-containing gas and the inert gas. By supplying the first element-containing gas, a first element-containing layer is formed on each of the wafers 200 (base film on a surface). The first element-containing layer may be a first element layer containing a halogen, may be an adsorption layer of molecules of the first element-containing gas or some of the molecules, or may include all of them. Note that a time during which only the first element-containing gas and the inert gas are supplied is a predetermined time T1. The supply of the inert gas performed in parallel during the time T1 is referred to as a (d1) step.

### First Reducing Gas Supply

After a lapse of a predetermined time (T1) from start of supply of the first element-containing gas, for example, 0.01 to 5 seconds after the start, the valve 324 is opened to cause a first reducing gas which is a reducing gas to flow into the gas supply pipe 320. A flow rate of the first reducing gas is adjusted by the MFC 322, and the first reducing gas is supplied from the gas supply holes 420a of the nozzle 420 into the process chamber 201 and discharged from the exhaust pipe 231. At this time, the valve 524 is opened to cause an inert gas to flow into the gas supply pipe 520. A flow rate of the inert gas which has flowed through the gas supply pipe 520 is adjusted by the MFC 522, and the inert gas is supplied into the process chamber 201 together with the first reducing gas and discharged from the exhaust pipe 231. At this time, the valve 534 is opened to cause the inert gas to flow into the gas supply pipe 530 in order to prevent entry of the first element-containing gas and the first reducing gas into the nozzle 430. The inert gas is supplied into the process chamber 201 via the gas supply pipe 330 and the nozzle 430 and discharged from the exhaust pipe 231. At this time, the first element-containing gas, the first reducing gas, and the inert gas are simultaneously supplied to the wafers 200. That is, there is a period (timing) during which at least the first element-containing gas and the first reducing gas are supplied in parallel. This period is also referred to as first processing. Note that a period during which the first processing is performed is also referred to as a first timing. The time during which the first element-containing gas and the first reducing gas are simultaneously supplied is referred to as S1. Here, preferably, time S1>time T1. With such a configuration, it is possible to suppress adsorption of a hydrogen halide to surfaces of the wafers 200 and to enhance an effect of removing a hydrogen halide in the process chamber 201. In addition, by setting the temperature of the wafers 200 (in the process chamber 201) to a temperature (decomposable atmosphere) at which the first reducing gas can be decomposed, the effect of removing a hydrogen halide can be enhanced. Here, the temperature at which the first reducing gas can be decomposed is, for example, 400 to 700 °C.

Here, the hydrogen halide is at least one of hydrogen chloride (HCl), hydrogen fluoride (HF), hydrogen iodide (HI), hydrogen bromide (HBr), and the like. The hydrogen halide is a by-product generated by a reaction between a halogen contained in the first element-containing gas and a hydrogen element-containing group present on the wafers 200. When the first element-containing gas is a gas containing chlorine (CI) and at least one of the first reducing gas and the second reducing gas is a gas containing hydrogen, HCl is generated as a hydrogen halide.

At this time, the APC 243 is adjusted to set a pressure in the process chamber 201 to a pressure within a range of, for example, 130 to 3990 Pa, preferably 500 to 2660 Pa, more preferably 600 to 1500 Pa. When the pressure in the process chamber 201 is lower than 130 Pa, there is a possibility that the second element contained in the first reducing gas enters the first element-containing layer, the content of the second element contained in a film to be formed increases, and a film containing the second element in addition to the first element is obtained. Similarly, also when the pressure in the process chamber 201 is higher than 3990 Pa, there is a possibility that the second element contained in the first reducing gas enters the first element-containing layer and a film having a high second element content contained in a film to be formed is obtained. As described above, even if the pressure in the process chamber 201 is too low or too high, the elemental composition of a film to be formed changes. A supply flow rate of the first reducing gas controlled by the MFC 322 is set to be equal to or higher than the flow rate of the first element-containing gas. The supply flow rate is within a range of, for example, 0.1 to 5 slm, preferably 0.3 to 3 slm, more preferably 0.5 to 2 slm. Each of the supply flow rates of the inert gas controlled by the MFCs 512, 522, and 532 is within a range of, for example, 0.01 to 20 slm, preferably 0.1 to 10 slm, more preferably 0.1 to 1 slm.

Here, when the temperature in the process chamber 201 or the temperature of the wafers 200 is high, there is a problem that the first reducing gas is decomposed and the second element contained in the first reducing gas is taken into a film to be formed on each of the wafers 200.

Here, the case where the temperature is high is, for example, a case where the temperature is 400 to 700 °C. The decomposition reaction of the first reducing gas can be suppressed by increasing the supply amount of the inert gas supplied when the first reducing gas is supplied. As illustrated in FIGS. 5 and 6, the supply amount of the inert gas is preferably increased when the first reducing gas is supplied. The supply amount of the inert gas is adjusted within a range of, for example, 0.1 to 20 slm, preferably 1 to 10 slm by the MFCs 512, 522, 532, and the like.

After a lapse of a predetermined time from start of the supply of the first element-containing gas, for example, 0.01 to 10 seconds after the start, the valve 314 of the gas supply pipe 310 is closed to stop the supply of the first element-containing gas. That is, a time (T1+S1) during which the first element-containing gas is supplied to the wafers 200 is within a range of, for example, 0.01 to 10 seconds. Note that the time (step) during which the first element-containing gas is supplied to the wafers is the step (a) illustrated in FIGS. 5 and 6. After the supply of the first element-containing gas is stopped, the first reducing gas and the inert gas are supplied to the wafers 200 for a predetermined time S2. Processing in which the first reducing gas is supplied without supplying the first element-containing gas to the wafers 200 in this manner is referred to as second processing. Note that a period during which the second processing is performed is also referred to as a second timing. A time (S1+S2) during which the first reducing gas is supplied to the wafers 200 is the step (b) illustrated in FIGS. 5 and 6. In addition, the inert gas is continuously supplied from the gas supply pipes 510 and 530 to the process chamber 201 via the gas supply pipes 310 and 330 and the nozzles 410 and 430. As a result, entry of the first reducing gas from the process chamber 201 into the nozzles 410 and 430 can be suppressed. A step of increasing the supply amount of the inert gas as compared with the supply amount in the step (d1) in parallel with the step (b) illustrated in FIGS. 5 and 6 is a step (d2). When the supply flow rate of the inert gas in the step (d1) is referred to as a first supply flow rate and the supply flow rate of the inert gas in the step (d2) is referred to as a second supply flow rate, a relationship of first supply flow rate<second supply flow rate is satisfied.

With this relationship, in the step (d1), inhibition of supply of molecules of the first element-containing gas to the wafers 200 can be suppressed. In the step (d2), a decomposition reaction of the first reducing gas can be suppressed.

As the first reducing gas, for example, an H-containing gas containing a hydrogen element (H) can be used. Examples of the H-containing gas include gases composed of a hydrogen element alone, such as an H₂ gas and a deuterium (D₂) gas. In addition, for example, a gas containing H and a silicon element (silicon hydride gas), such as a monosilane (SiH₄) gas, a disilane (Si₂H₆) gas, or a trisilane (Si₃H₈) gas can be used. In addition, for example, a gas containing H and a boron element (borohydride gas), such as a monoborane (BH₃) gas, a diborane (B₂H₆) gas, or a triborane (B₃H₈) gas can be used. In addition, for example, a phosphine (PH₃) gas, an activated hydrogen-containing gas, or a trisdimethylaminosilane (SiH[N(CH₃)₂]₃) gas can be used. A gas that can be decomposed in the process chamber 201 is preferably used. Examples of the gas include a silicon hydride gas. A gas of a substance different from that of a second reducing gas described later is preferably selected.

### [Second Step S304] (Residual Gas Removal)

After a lapse of a predetermined time from start of the supply of the first reducing gas, for example, 0.01 to 60 seconds, preferably 0.1 to 30 seconds, more preferably 1 to 20 seconds after the start, the valve 324 is closed to stop the supply of the first reducing gas. That is, a time during which the first reducing gas is supplied to the wafers 200 is within a range of, for example, 0.01 to 60 seconds, preferably 0.1 to 30 seconds, more preferably 1 to 20 seconds. If the time during which the first reducing gas is supplied to the wafers 200 is shorter than 0.01 seconds, there is a possibility that a hydrogen halide which is a growth inhibiting factor is not sufficiently reduced by the first reducing gas and remains in the Ti-containing layer. If the time during which the first reducing gas is supplied to the wafers 200 is longer than 60 seconds, there is a possibility that the second element contained in the first reducing gas enters the first element-containing layer and a film having a high second element content contained in a film to be formed is obtained. The supply time of the first reducing gas is preferably set to be longer than the supply time of the first element-containing gas. In addition, the supply time (S2) of the first reducing gas after the supply of the first element-containing gas is stopped is set to be equal to or longer than S1. That is, a relationship of S2≥S1 is satisfied. With such a configuration, the halogen component in the first element-containing layer can be reduced, and an effect of removing a hydrogen halide in the process chamber 201 can be enhanced.

Next, at the same time as stopping the supply of the first reducing gas, the supply amount of the inert gas from the nozzles 410, 420, and 430 into the process chamber 201 is increased. In addition, with the APC 243 of the exhaust pipe 231 open, the pump 246 discharges the atmosphere in the process chamber 201 to exclude, from the process chamber 201, the first element-containing gas and the first reducing gas that remain in the process chamber 201 and are unreacted or have contributed to the formation of the first element-containing layer. At this time, with the valves 514, 524, and 534 open, the supply of the inert gas into the process chamber 201 is maintained. The inert gas acts as a purge gas, which makes it possible to enhance an effect of excluding, from the process chamber 201, the first element-containing gas and the first reducing gas that remain in the process chamber 201 and are unreacted or have contributed to the formation of the first element-containing layer. Here, a hydrogen halide which is a growth inhibiting factor is discharged from the process chamber 201 as a reaction by-product generated by reacting with the first reducing gas. The first reducing gas remaining in the process chamber 201 is diluted with the inert gas and discharged to the exhaust pipe 231. Note that, as illustrated in FIGS. 5 and 6, an inert gas supply step performed after the supply of the first reducing gas is stopped is a step (g).

Each of the MFCs 512, 522, and 532 is controlled such that the total flow rate of the inert gas from the nozzles 410, 420, and 430 is 10 to 60 slm. The total flow rate is preferably 60 slm. The APC opening degree is 0% to 70%. Either or both of the valve opening degree of the APC 243 and the flow rates of the MFCs 512, 522, and 532 are controlled such that a pressure Pa2 in the process chamber 201 at this time is equal to a pressure Pa1 at the time of supplying the first reducing gas. The pressure Pa2 is, for example, 1 Torr to 20 Torr, and is specifically set to 10 Torr. Processing of maintaining the pressure Pa2 in the process chamber 201 substantially equal to the pressure Pa1 at the time of supplying the SiH₄ gas in this manner is referred to as third processing. A period during which the third processing is performed is also referred to as a third timing.

### Pressures Pa1 and Pa2

Here, a pressure ratio between the pressure Pa1 and the pressure Pa2 is affected by dimensions of each portion of the substrate processing apparatus 10, the number of wafers 200, the surface area of each of the wafers 200, and the like. Examples of the dimensions of each portion of the substrate processing apparatus 10 include the volume of the process chamber 201, the lengths of the nozzles 410, 420, and 430, the lengths of the gas supply pipes 310, 320, and 330, the volume of the exhaust pipe 231, and the position and diameter of the APC 243. A relationship of the pressure ratio between Pa1 and Pa2 may be, for example, a relationship of Pa1=Pa2×±50%. The valve opening degree of each of the MFCs 512, 522, and 532 and the APC 243 is preferably controlled so as to satisfy a relationship of Pa1=Pa2×±10%. The pressure of Pa2 can be controlled by either or both of the flow rates of the MFCs 512, 522, and 532 and the valve opening degree of the APC 243.

### Inert Gas Flow Rate

Here, the flow rates of the inert gas supplied to the nozzles 410, 420, and 430 are controlled by the MFCs 512, 522, and 532, respectively. The flow rates of the inert gas supplied to the nozzles 410, 420, and 430 may be controlled so as to be equal to each other, but preferably, the flow rate of the inert gas supplied to the nozzle 420 that has supplied the first reducing gas is made higher than the flow rates of the inert gas supplied to the other nozzles 410 and 430. With such a configuration, discharge efficiency of the first reducing gas present in the nozzle 420 can be improved.

### Inert Gas Supply Time Pt1

Next, an inert gas supply time Pt1 will be described with reference to FIG. 5. The time Pt1 during which an inert gas is supplied and the pressure Pa2 is maintained is set to be at least equal to or longer than the time S2 during which the first reducing gas is supplied after the supply of the first element-containing gas is stopped. With such a configuration, the concentrations of the first reducing gas and a by-product in the process chamber 201 can be reduced. Note that Pt1 may be set to a time Pt2 equivalent to that in the subsequent purge step S306. A relationship of Pt1≤Pt2 is satisfied. Pt1 may be set to a value longer than this. However, since a time of the entire film forming step S300 is longer and affects a manufacturing throughput of a semiconductor manufacturing apparatus, Pt1 is set so as to satisfy this relationship.

### Improvement of Discharge Efficiency

Next, improvement of discharge efficiency of a residual gas and a reaction by-product on the wafers 200 (in the process chamber 201) will be described. In FIG. 5, the processing of increasing the flow rate of the inert gas simultaneously with the stop of the supply of the first reducing gas has been described, but the present disclosure is not limited thereto, and a gas supply sequence as illustrated in FIG. 6 may be configured. In the second step S304, after a step (g1) of increasing the supply amount of the inert gas and discharging the atmosphere for a predetermined time is performed, the opening degree of the APC 243 is set to a second opening degree increased from a first opening degree. A step (g2) of reducing a pressure in the process chamber 201 and discharging the atmosphere is performed by increasing the opening degree of the APC 243. In FIG. 6, as an example, the opening degree of the APC 243 is set to the second opening degree. The second opening degree is, for example, 100% (full open). Here, the example in which the second opening degree is set to 100% has been described, but the present disclosure is not limited thereto, and the opening degree may be any opening degree as long as the pressure can be lowered. In S304, the second opening degree may be any degree as long as the pressure in the process chamber 201 is lowered after the supply amount of the inert gas is increased. For example, the second opening degree is larger than 50% and equal to or less than 100%. By increasing the opening degree of the exhaust valve 243 to discharge the atmosphere on the wafers 200 at the second pressure Pa2 lower than the first pressure Pa1, the discharge efficiency of the residual gas and the reaction by-product can be improved. Note that the full open does not necessarily mean that the degree of valve opening is 100%, and may allow an error of −10%. The error is preferably −5%. Note that the degree of valve opening including such an error is also referred to as approximately fully opened or substantially fully opened.

### [Third Step S305] (Second Reducing Gas Supply)

After the residual gas in the process chamber 201 is removed, the valve 334 is opened to cause the second reducing gas as a reactant gas to flow into the gas supply pipe 330. A flow rate of the second reducing gas is adjusted by the MFC 332, and the second reducing gas is supplied from the gas supply holes 430a of the nozzle 430 into the process chamber 201 and discharged from the exhaust pipe 231. At this time, the second reducing gas is supplied to the wafers 200. At this time, the valve 534 is opened to cause the inert gas to flow into the gas supply pipe 530. A flow rate of the inert gas which has flowed through the gas supply pipe 530 is adjusted by the MFC 532. The inert gas is supplied together with the second reducing gas into the process chamber 201 and discharged from the exhaust pipe 231. At this time, the valves 514 and 524 are opened to cause the inert gas to flow into the gas supply pipes 510 and 520 in order to prevent entry of the second reducing gas into the nozzles 410 and 420. The inert gas is supplied into the process chamber 201 via the gas supply pipes 310 and 320 and the nozzles 410 and 420 and discharged from the exhaust pipe 231.

At this time, the APC 243 is adjusted to set a pressure in the process chamber 201 to a pressure within a range of, for example, 1 to 3990 Pa. The second reducing gas supply flow rate controlled by the MFC 332 is a flow rate within a range of, for example, 0.1 to 30 slm. Each of the supply flow rates of the inert gas controlled by the MFCs 512, 522, and 532 is within a range of, for example, 0.1 to 30 slm. A time during which the second reducing gas is supplied to the wafers 200 is within a range of, for example, 0.01 to 30 seconds. The temperature of the heater 207 at this time is set to a similar temperature to that in the first element-containing gas supply step.

At this time, gases flowing into the process chamber 201 are the second reducing gas and the inert gas. The second reducing gas undergoes a substitution reaction with at least a part of the first element-containing layer formed on each of the wafers 200 in the first step S303. At the time of the substitution reaction, the first element contained in the first element-containing layer and a third element contained in the second reducing gas are bonded to form, on each of the wafers 200, a layer containing the first element and the third element, the layer containing the first element and the third element and containing substantially no second element.

As the second reducing gas, an H-containing gas containing a hydrogen element can be used. As hydride containing nitrogen (N) as the third element, such as an ammonia (NH₃) gas, a hydrazine (N₂H₄) gas, a diazene (N₂H₂) gas, or a heavy ammonia (ND₃) gas is preferably used.

### [Fourth Step S306] (Residual Gas Removal)

After the layer containing the first element and the third element is formed, the valve 334 is closed to stop the supply of the second reducing gas. Then, by a processing procedure similar to that in the second step described above, the second reducing gas that remains in the process chamber 201 and is unreacted or has contributed to the formation of the layer containing the first element and the third element, and a reaction by-product are excluded from the process chamber 201. Note that the valve opening degree of the APC 243 is set to be approximately fully opened (approximately 100%), the total flow rate of the inert gas is set to 1 slm to 100 slm, and specifically, each MFC and the APC 243 are controlled such that 180 Pa is obtained at 60 slm. A pressure Pa4 here is a pressure sufficiently lower than the above-described pressure Pa2 and a pressure Pa3 in the third step S305, and relationships of Pa4<Pa2 and Pa4<Pa3 are satisfied.

With such a configuration, a by-product generated in one cycle can be discharged, and an influence on the next cycle can be reduced.

### Determination Step

A cycle of sequentially performing the first step S303 to the fourth step S306 described above is performed a predetermined number of times (n times, n is 1 or an integer of 2 or more) to form a predetermined film having a predetermined thickness on the wafer 200.

Note that when a TiN film is formed on each of the wafers 200, the following gases can be used.

First element-containing gas: a gas containing a metal element (for example, Ti) serving as the first element and a halogen element (for example, Cl).

First reducing gas: a gas containing Si serving as the second element and H. Examples of the gas include a silicon hydride gas.

Second reducing gas: a gas containing N serving as the third element and H.

The hydrogen halide in the case of using these gases is HCl.

In the present disclosure, a “TiN film containing no Si atom” includes not only a case where the TiN film contains no Si atom at all, but also a case where the Si content in the TiN film is extremely low, such as a case where the TiN film contains almost no Si atom or a case where the TiN film contains substantially no Si atom. For example, a case where the Si content in the TiN film is about 4%, preferably 4% or less is also included.

### Atmosphere Adjustment Step S307

An inert gas is supplied from each of the gas supply pipes 510, 520, and 530 into the process chamber 201 and discharged from the exhaust pipe 231. The inert gas acts as a purge gas, whereby the inside of the process chamber 201 is purged with the inert gas, and a gas remaining in the process chamber 201 and a by-product are removed from the process chamber 201. Thereafter, the atmosphere in the process chamber 201 is replaced with the inert gas, and the pressure in the process chamber 201 is returned to a normal pressure (atmospheric pressure).

### Substrate Unloading Step S308

Thereafter, the cap 219 is lowered by the elevator 115, and a lower end of the reaction tube 203 is opened. Then, the processed wafers 200 are unloaded from the lower end of the reaction tube 203 to the outside of the reaction tube 203 in a state of being supported by the boat 217.

Thereafter, the processed wafers 200 are taken out from the boat 217.

### (3) Effects of the Present Embodiment

According to an example of the present embodiment, one or more effects described below can be obtained. (a) HCl that is generated during film formation and decreases a deposition rate can be efficiently discharged, and the deposition rate can be increased. (b) A second element concentration in a film can be reduced. (c) Resistivity can be reduced. (d) Oxidation resistance is improved. (e) The first reducing gas in the process chamber can be diluted with an inert gas and discharged from the process chamber to an exhauster, and a gas having a high first reducing gas concentration can be prevented from being instantaneously discharged to the exhauster. This makes it possible to suppress an unexpected reaction of the first reducing gas at a subsequent stage of the pump. (f) Decomposition of the first reducing gas on the wafers 200 (in the process chamber 201) can be suppressed. (g) Even when the wafers 200 (in the process chamber 201) are in a high temperature state, decomposition of the first reducing gas can be suppressed.

In the above description, each of the first reducing gas and the second reducing gas is described using one kind of gas. Not limited thereto, two or more kinds of reducing gases (hydrogen-containing gases) may be used as each of the first reducing gas and the second reducing gas. For example, a gas composed of hydrogen alone and a silicon hydride gas may be used as the first reducing gas. When a gas composed of hydrogen alone is supplied as the first reducing gas in addition to the silicon hydride gas, a reaction in which the silicon hydride gas is decomposed into silicon and hydrogen can be suppressed. That is, the decomposition reaction of the silicon hydride gas can be further suppressed together with the above-described effects.

In addition, in the above description, the configuration in which the first element-containing gas and the first reducing gas are supplied from the nozzles 410 and 420, respectively, into the process chamber 201 has been described, but the present disclosure is not limited thereto, and the first element-containing gas and the first reducing gas may be premixed and supplied from one nozzle.

In addition, in the above description, the configuration in which the supply of the first reducing gas is started after the supply of the first element-containing gas is started has been described, but the present disclosure is not limited thereto, and the supply of the first reducing gas may be started simultaneously with the start of the supply of the first element-containing gas. In addition, the supply of the first reducing gas may be stopped simultaneously with the stop of the supply of the first element-containing gas. In this way, at least one of the effects described in the present disclosure can be obtained.

In the above description, a case where the above-described substrates processing sequence is continuously performed (in-situ) in the same process chamber (process container) has been described. The present disclosure is not limited to the above-described aspect, and the steps of the above-described substrate processing sequence may be performed (ex-situ) in different process chambers (process containers).

In the above-described aspect, an example has been described in which a film is formed using a batch type substrate processing apparatus that processes a plurality of substrates at a time. The present disclosure is not limited to the above-described aspect, and can be suitably applied to, for example, a case where a film is formed using a single wafer type substrate processing apparatus that processes one or more substrates at a time. In the above-described aspect, an example has been described in which a film is formed using a substrate processing apparatus including a hot wall type process furnace. The present disclosure is not limited to the above-described aspect, and can be suitably applied to a case where a film is formed using a substrate processing apparatus including a cold wall type process furnace.

In addition, in the above description, an example in which a wafer serving as a semiconductor substrate is used has been described, but the present disclosure can be applied to a case where substrate processing is performed using a substrate made of another material, for example, a material such as a ceramic substrate or a glass substrate.

The above-described aspect and modified examples can be used in combination as appropriate. Processing procedures and processing conditions at this time can be similar to, for example, the processing procedures and processing conditions in the aspect and modified examples described above.

The aspect of the present disclosure and modified examples have been specifically described above. However, the aspect of the present disclosure and modified examples are not limited to the above-described aspect and modified examples, and various modifications can be made without departing from the gist of the present disclosure.

According to the present disclosure, a low-resistance film can be formed.

### FIG. 3

123 EXTERNAL MEMORY
122 INPUT/OUTPUT DEVICE
121c MEMORY
121d I/O PORT
312, 322, 332, 512, 522, 532 MASS FLOW CONTROLLER
314, 324, 334, 514, 524, 534 VALVE
245 PRESSURE SENSOR
243 APC VALVE
246 VACUUM PUMP
207 HEATER
263 TEMPERATURE SENSOR
267 ROTATION MECHANISM
115 BOAT ELEVATOR

### FIG. 4

S301 SUBSTRATE LOADING STEP
S302 ATMOSPHERE ADJUSTMENT STEP
S300 FILM FORMING STEP
S307 ATMOSPHERE ADJUSTMENT STEP
S308 SUBSTRATE UNLOADING STEP

### FIG. 5

ONE CYCLE
FIRST ELEMENT-CONTAINING GAS SUPPLY
FIRST REDUCING GAS SUPPLY
SECOND REDUCING GAS SUPPLY
INERT GAS SUPPLY
EXHAUST VALVE OPENING DEGREE
PRESSURE

### FIG. 6

ONE CYCLE
FIRST ELEMENT-CONTAINING GAS SUPPLY
FIRST REDUCING GAS SUPPLY
SECOND REDUCING GAS SUPPLY
INERT GAS SUPPLY
EXHAUST VALVE OPENING DEGREE
PRESSURE

What is claimed is:

1. A method of processing a substrate, comprising:
(a) supplying a first element-containing gas to a substrate;
(b) supplying a first reducing gas to the substrate;
(c) supplying a second reducing gas to the substrate;
(d) supplying an inert gas to the substrate;
(e) performing (a) and (b) at least partially in parallel while performing (d), and, when performing (b), increasing a supply flow rate of the inert gas as compared with a supply flow rate of the inert gas before starting (b); and
(f) performing (e) and (c) a predetermined number of times to form a film containing the first element on the substrate.

2. The method of claim 1, wherein:
in (e), after (a) and (d) are started, (b) is started.

3. The method of claim 2, wherein:
in (e), after the inert gas is supplied at a first supply flow rate,
when (b) is performed, a supply flow rate of the inert gas is increased to a second supply flow rate higher than the first supply flow rate.

4. The method of claim 1, further comprising a step (g) of supplying the inert gas between (e) and (c) in (f).

5. The method of claim 3, further comprising a step (g) of supplying the inert gas between (e) and (c) in (f).

6. The method of claim 5, wherein:
in (g), the supply flow rate of the inert gas is set to a third supply flow rate higher than the second supply flow rate.

7. The method of claim 1, wherein:
in (e), the supply flow rate of the inert gas is set to be higher than the supply flow rate of the first reducing gas.

8. The method of claim 6, wherein:
the third supply flow rate is higher than the supply flow rate of the first reducing gas.

9. The method of claim 4, wherein:
(g) has a period during which an atmosphere in a space containing the substrate is discharged at a first opening degree of an exhaust valve disposed in a path through which the atmosphere is discharged, and a period during which the atmosphere is discharged at a second opening degree larger than the first opening degree.

10. The method of claim 4, wherein:
(g) has a period during which an atmosphere is discharged at a first pressure in a space containing the substrate, and a period during which the atmosphere is discharged at a second pressure lower than the first pressure.

11. The method of claim 1, further comprising a step (h) of continuing the supply of the first reducing gas and the supply of the inert gas after (e), wherein:
in (e) and (h), a pressure in a space containing the substrate is maintained.

12. The method of claim 1, wherein:
(f) is performed in an atmosphere in which the first reducing gas can be decomposed.

13. The method of claim 1, wherein:
the first element-containing gas is a gas containing a first element and a halogen element.

14. The method of claim 1, wherein:
the first reducing gas is a gas containing hydrogen and is a gas of a substance different from that of the second reducing gas.

15. The method of claim 14, wherein:
the second reducing gas is a gas containing hydrogen.

16. The method of claim 13, wherein:
the first element is a metal element, the first reducing gas contains a Group 14 element, and the second reducing gas is a gas containing nitrogen.

17. A method of manufacturing a semiconductor device, comprising the method of claim 1.

18. A non-transitory computer-readable recording medium storing a program that causes, by a computer, a substrate processing apparatus to perform:
(a) supplying a first element-containing gas to a substrate;
(b) supplying a first reducing gas to the substrate;
(c) supplying a second reducing gas to the substrate;
(d) supplying an inert gas to the substrate;
(e) performing (a) and (b) at least partially in parallel while performing (d), and, when performing (b), increasing a supply flow rate of the inert gas as compared with a supply flow rate of the inert gas before starting (b); and
(f) performing (e) and (c) a predetermined number of times to form a film containing the first element on the substrate.

19. A substrate processing apparatus comprising:
a first gas supplier configured to supply a first element-containing gas to a substrate;
a second gas supplier configured to supply a first reducing gas to the substrate; a third gas supplier configured to supply a second reducing gas to the substrate; a fourth gas supplier configured to supply an inert gas to the substrate; and
a controller configured to be able to control the first supplier, the second supplier, the third supplier, and the fourth supplier so as to cause the first to fourth suppliers to perform:
(a) supplying a first element-containing gas to the substrate;
(b) supplying a first reducing gas to the substrate;
(c) supplying a second reducing gas to the substrate;
(d) supplying an inert gas to the substrate;
(e) performing (a) and (b) at least partially in parallel while performing (d), and, when performing (b), increasing a supply flow rate of the inert gas as compared with a supply flow rate of the inert gas before starting (b); and
(f) performing (e) and (c) a predetermined number of times to form a film containing the first element on the substrate.
